(19) United States
(12) Patent Application Publication
(10) Pub. No.: US 2025/0225285 A1
(43) Pub. Date: Jul. 10, 2025

(54) HOUSE MODEL GENERATION DEVICE, HOUSE MODEL GENERATION METHOD, AND PROGRAM

(71) Applicant: FUJIFILM Corporation, Tokyo (JP)

(72) Inventor: Kyota WATANABE, Tokyo (JP)

(73) Assignee: FUJIFILM Corporation, Tokyo (JP)

(21) Appl. No.: 19/089,909

(22) Filed: Mar. 25, 2025

Related U.S. Application Data
(63) Continuation of application No. PCT/JP2023/032834, filed on Sep. 8, 2023.

(30) Foreign Application Priority Data
Sep. 28, 2022 (JP) 2022-154750

(51) Int. Cl. G06F 30/13; G06T 19/20

(52) U.S. Cl. CPC G06F 30/13; G06T 19/20; G06T 2200/24; G06T 2210/04; G06T 2219/2004; G06T 2219/2021

(57) ABSTRACT

There are provided a house model generation device, a house model generation method, and a program that can easily generate a house model having necessary and sufficient accuracy according to a purpose of use. A house model generation device (100) includes a processor (110). The processor (110) receives selection of a purpose of use of a house model to be generated among a plurality of purposes of use, receives designation of one part type among a plurality of generatable part types according to the selected purpose of use, receives an input point input by being designated on a display unit, and generate a part model, which corresponds to the designated part type and constitutes the house model, based on the input point and the interpretation information.

### CROSS-REFERENCE TO RELATED APPLICATIONS

The present application is a Continuation of PCT International Application No. PCT/JP2023/032834 filed on Sep. 8, 2023 claiming priority under 35 U.S.C § 119 (a) to Japanese Patent Application No. 2022-154750 filed on Sep. 28, 2022. Each of the above applications is hereby expressly incorporated by reference, in its entirety, into the present application.

### BACKGROUND OF THE INVENTION

### 1. Field of the Invention

The present invention relates to a house model generation device, a house model generation method, and a program.

### 2. Description of the Related Art

In the related art, a technique of generating a three-dimensional model according to a purpose has been proposed.

For example, JP2009-258823A proposes a technique for generating a three-dimensional model from a two-dimensional drawing to allow a user to visually and intuitively recognize an indoor space from a design stage of a building such as a house.

### SUMMARY OF THE INVENTION

Currently, three-dimensional models are used for various purposes. For example, three-dimensional models are used in a residence damage certification survey in a case of a disaster, a house survey related to a fixed property tax (a fixed property tax survey), an urban planning survey, and a vacant house management service. Further, these three-dimensional models are generated by a dedicated generation device for each purpose of use. Therefore, in a case where a three-dimensional model for a different purpose of use is to be generated, the three-dimensional model should be generated using another generation device. For this reason, the three-dimensional model could not be efficiently generated.

In JP2009-258823A described above, only the generation of the three-dimensional model in a case of designing a building such as a house is mentioned and the generation of three-dimensional models for other purposes is not mentioned.

The present invention has been made in view of such circumstances, and an object of the present invention is to provide a house model generation device, a house model generation method, and a program that can efficiently generate house models for different purposes of use.

A house model generation device according to an aspect of the present invention, which is for achieving the above object, comprises: a memory that stores information on a plurality of part types of part models, which are generatable according to each of a plurality of purposes of use of a three-dimensional house model and constitute the house model, and interpretation information on a relationship between an input point and a feature point of a part for each of the plurality of part types; and a processor. The processor is configured to: receive selection of a purpose of use of the house model to be generated among the plurality of purposes of use; receive designation of one part type among a plurality of generatable part types according to the selected purpose of use; receive the input point input by being designated on a display unit; and generate a part model, which corresponds to the designated part type and constitutes the house model, based on the input point and the interpretation information.

Preferably, the memory stores information on a shape input menu to which information on shapes of the plurality of part types is to be input according to each of the plurality of purposes of use, and the processor is configured to: receive an input of the shape input menu according to the designated part type; and generate a part model, which corresponds to the designated part type and constitutes the house model, based on the input of the shape input menu.

Preferably, the plurality of purposes of use of the house model include two or more purposes of a residence damage certification survey service, a fixed property tax survey service, an urban planning service, and a vacant house management service.

Preferably, the interpretation information in a case where the part type is an exterior wall of a first floor is information on a relationship in which the input point forms a feature point of the exterior wall of the first floor in a case where a point on a ground surface on the display unit is input as the input point.

Preferably, the interpretation information in a case where the part type is an exterior wall of a second floor or higher is information on a relationship in which the input point forms a feature point of the exterior wall of the second floor or higher in a case where a point in a ceiling surface of an immediately lower floor on the display unit is input as the input point.

Preferably, the interpretation information in a case where the part type is a window is information on a relationship in which the input point forms a feature point of the window in a case where a point in a surface of an exterior wall on the display unit is input as the input point.

Preferably, the interpretation information in a case where the part type is a door is information on a relationship in which the input point forms a feature point of the door in a case where a point in a surface of an exterior wall on the display unit is input as the input point.

Preferably, the interpretation information in a case where the part type is an exterior wall is information on a relationship in which the input point forms a feature point of the exterior wall in a case where a point on the display unit is input as the input point, and the part models of the exterior wall and a roof provided on the exterior wall are generated based on the input point and the interpretation information.

Preferably, the processor is configured to: receive selection of a portion on the part model on the display unit; and store state information of the part model in association with the selected portion.

Preferably, the processor is configured to dispose an image, which indicates state information of the part model, on a surface of the part model displayed on the display unit.

Preferably, the processor is configured to: display the generated part model on the display unit; and receive an instruction to move a position of the part model.

Preferably, the part types are an exterior wall, an interior wall, a roof, a foundation, a column, a beam, a floor, a ceiling, a building fixture, a window, a door, and equipment.

A house model generation method according to another aspect of the present invention is a house model generation method executed by a processor of a house model generation device including a memory that stores information on a plurality of part types of part models, which are generatable according to each of a plurality of purposes of use of a three-dimensional house model and constitute the house model, and interpretation information on a relationship between an input point and a feature point of a part for each of the plurality of part types, and the processor. The house model generation method comprises: a step of receiving selection of a purpose of use of the house model to be generated among the plurality of purposes of use; a step of receiving designation of one part type among a plurality of generatable part types according to the selected purpose of use; a step of receiving the input point input by being designated on a display unit; and a step of generating a part model, which corresponds to the designated part type and constitutes the house model, based on the input point and the interpretation information.

A program according to another aspect of the present invention is a program executed by a processor of a house model generation device including a memory that stores information on a plurality of part types of part models, which are generatable according to each of a plurality of purposes of use of a three-dimensional house model and constitute the house model, and interpretation information on a relationship between an input point and a feature point of a part for each of the plurality of part types, and the processor. The program comprises: a step of receiving selection of a purpose of use of the house model to be generated among the plurality of purposes of use; a step of receiving designation of one part type among a plurality of generatable part types according to the selected purpose of use; a step of receiving the input point input by being designated on a display unit; and a step of generating a part model, which corresponds to the designated part type and constitutes the house model, based on the input point and the interpretation information.

According to the present invention, the selection of a purpose of use of a house model is received and part models constituting the house model are generated according to the purpose of use. Accordingly, the part models can be efficiently generated.

### BRIEF DESCRIPTION OF THE DRAWINGS

FIG. 1 is a block diagram showing a hardware configuration of a house model generation device according to an embodiment.

FIG. 2 is a diagram showing a storage configuration example of part type information of a residence damage certification survey.

FIG. 3 is a diagram showing a storage configuration example of interpretation information of a residence damage certification survey.

FIG. 4 is a functional block diagram showing main functions of a processor.

FIG. 5 is a flowchart showing a house model generation method.

FIG. 6 is a diagram illustrating an example of a user interface.

FIG. 7 is a diagram illustrating input points designated on a display unit.

FIGS. 8A and 8B are diagrams showing an example of a part model of exterior walls of a first floor.

FIG. 9 is a diagram illustrating the adjustment of the position of a part model.

FIG. 10 is a diagram illustrating Specific example 1 of storage of state information.

FIG. 11 is a diagram illustrating Specific example 2 of storage of state information.

FIG. 12 is a diagram illustrating an example of a user interface.

FIG. 13 is a diagram illustrating an input point designated on the display unit.

FIG. 14 is a diagram showing an example of a part model of exterior walls of a first floor.

FIG. 15 is a diagram illustrating an example of a user interface.

FIG. 16 is a diagram illustrating a part model of a roof.

FIG. 17 is a diagram illustrating an example of a user interface.

FIG. 18 is a diagram illustrating another example of an input point reception step and a part model generation step.

FIG. 19 is a diagram illustrating another example of the input point reception step and the part model generation step.

### DESCRIPTION OF THE PREFERRED EMBODIMENTS

A house model generation device, a house model generation method, and a program according to preferred embodiments of the present invention will be described below with reference to the accompanying drawings.

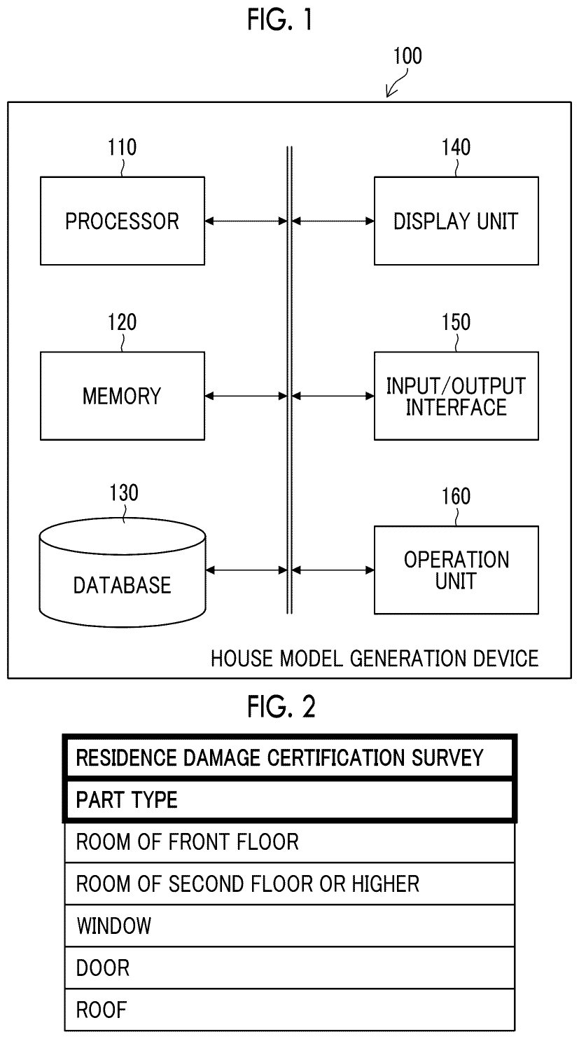

FIG. 1 is a block diagram showing a hardware configuration of a house model generation device 100 according to an embodiment. The house model generation device 100 is configured using a computer. The computer applied to the house model generation device 100 may be a server, a personal computer, or a workstation.

The house model generation device 100 comprises a processor 110, a memory 120, a database (a memory in the present invention) 130, a display unit 140, an input/output interface 150, and an operation unit 160.

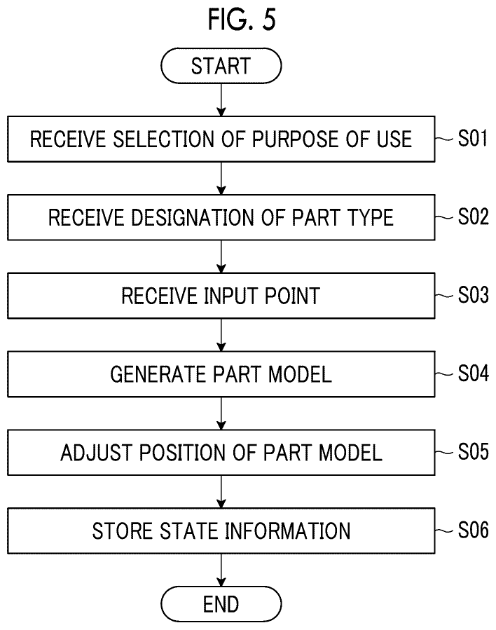

The processor 110 is configured of a central processing unit (CPU) or the like, and generally controls each part of the house model generation device 100. Further, the processor 110 performs processing related to a purpose-of-use selection step, a part type selection step, an input point reception step, a part model generation step, a position adjustment step, and a damage storage step that will be described later (see FIG. 5).

The memory 120 includes a flash memory, a read-only memory (ROM), a random access memory (RAM), a hard disk drive, and the like. The flash memory, the ROM, or the hard disk drive is a non-volatile memory that stores various programs and the like including an operating system. The RAM functions as a work region of the processing performed by the processor 110 and temporarily stores the programs or the like stored in the flash memory or the like. Further, a part (RAM) of the memory 120 may be built in the processor 110.

The database 130 stores programs and data that are required to generate a house model. For example, the database 130 stores part type information and interpretation information. Here, the part type information is information on a part type that can be generated according to the purpose of use of the house model. Specific examples of the part types include an exterior wall, an interior wall, a roof, a foundation, a column, a beam, a floor, a ceiling, a building fixture, a window, a door, and equipment. Further, the interpretation information is information on a relationship between input points and feature points of a part for each part type. Furthermore, the database 130 can also store information on a shape input menu. Here, the information on the shape input menu is information on the shape input menu that is used to input information on a shape for each part type. The database 130 stores the part type information, the interpretation information, and the information on the shape input menu, which have been described above, for each purpose of use. The database 130 can also provide the information, which is stored in the processor 110, via a network (not shown). In that case, the database 130 provides the information, which is stored in the processor 110, via the input/output interface 150.

FIG. 2 is a diagram showing a storage configuration example of the part type information, which is stored in the database 130, in a case where the purpose of use is a residence damage certification survey.

In the case of the residence damage certification survey, part models that can be generated are an exterior wall of a first floor, an exterior wall of a second floor or higher, a window, a door, and a roof. In the case of the residence damage certification survey, necessary and sufficient information can be recorded since a house model is generated using these part models. The house model includes one or two or more part models.

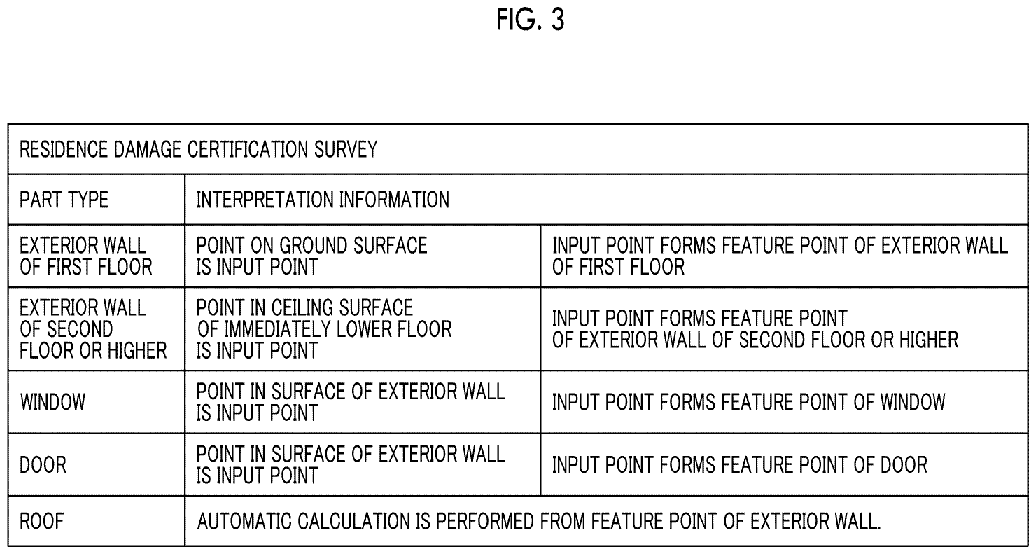

FIG. 3 is a diagram showing a storage configuration example of the interpretation information, which is stored in the database 130, in a case where the purpose of use is the residence damage certification survey.

In the residence damage certification survey, as described below, the part models are generated based on the interpretation information shown in FIG. 3 such that input points and feature points of the part models to be generated have a relationship. The input points to be described below are input on the display unit 140 via the operation unit 160 by a user.

In a case where points on the ground surface are designated as input points to generate a part model of exterior walls of a first floor, the part models of exterior walls of the first floor are generated such that the designated input points form feature points of exterior walls of the first floor. Further, in a case where points in a ceiling surface of the immediately lower floor are designated as input points to generate a part model of exterior walls of a second floor or higher, the part model of exterior walls of the second floor or higher are generated such that the designated input points form feature points of the exterior walls of the second floor or higher. Furthermore, in a case where points in the surface of the exterior wall are designated as input points to generate a part model of a window, the part model of a window is generated such that the designated input points form feature points of the window. In addition, in a case where points in the surface of the exterior wall are designated as input points to generate a part model of a door, the part model of a door is generated such that the designated input points form feature points of the door. Moreover, in a case where a part model of a roof is to be generated, the part model of a roof is generated with a predetermined model based on feature points of the exterior wall.

The part type information and the interpretation information in the residence damage certification survey described in FIGS. 2 and 3 are specific examples and are not limited thereto. Further, for example, part type information and interpretation information in each of a fixed property tax survey service, an urban planning survey service, and a vacant house management service are stored in the database 130 as in the residence damage certification survey, but description thereof will be omitted here.

Returning to FIG. 1, the display unit 140 performs various displays required to generate a house model in response to an instruction given from the processor 110. For example, the display unit 140 displays a user interface to which a user inputs information in a case of generating a house model, generated part models, and the house model that includes one or a plurality of part models. Further, the display unit 140 can also display state information that is stored in association with the generated house model, an image (for example, a damage image) that indicates the state information, and the like. Furthermore, the display unit 140 is also used as a part of a graphical user interface (GUI) in a case where various types of information are received from the operation unit 160. The processor 110 functions as a display control unit and controls the display of the display unit 140.

The input/output interface 150 includes a connection unit that can be connected to an external device, a communication unit that can be connected to a network, and the like. A universal serial bus (USB), a high-definition multimedia interface (HDMI) (HDMI is a registered trademark), or the like can be applied as the connection unit that can be connected to the external device.

The operation unit 160 includes a pointing device such as a mouse, a keyboard, and the like. Further, the display unit 140 also functions as a part of the operation unit 160 that receives various types of information and an instruction input by user operations.

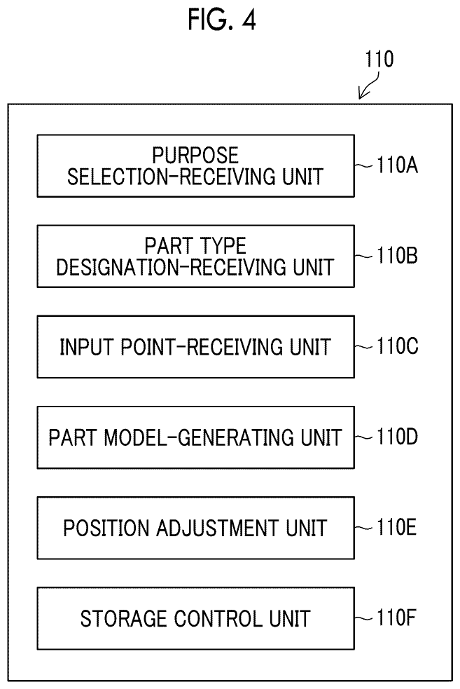

FIG. 4 is a functional block diagram showing main functions of the processor 110 of the house model generation device 100 shown in FIG. 1. The processor 110 can implement functions to be described below by executing a dedicated program stored in the memory 120 or the database 130.

The processor 110 includes a purpose selection-receiving unit 110A, a part type designation-receiving unit 110B, an input point-receiving unit 110C, a part model-generating unit 110D, a position adjustment unit 110E, and a storage control unit 110F. The purpose selection-receiving unit 110A receives selection of the purpose of use of a house model, which is generated, in response to an input from the user. The part type designation-receiving unit 110B receives designation of one part type from a plurality of part types, which can be generated, according to the selected purpose of use in response to an input from the user. The input point-receiving unit 110C receives input points that are input by being designated on the display unit 140 by a user. The part model-generating unit 110D generates a part model, which corresponds to the designated part type, based on the input points and the interpretation information. The position adjustment unit 110E receives an instruction to move the position of the generated part model displayed on the display unit 140, and moves the position of the part model. The storage control unit 110F receives selection of a portion on the part model on the display unit 140, and state information of the part model is stored in association with the selected portion by the storage control unit 110F.

Next, a house model generation method performed using the house model generation device 100 will be described. The processor 110 executes the dedicated program stored in the memory 120 or the database 130, so that the house model generation method is performed.

FIG. 5 is a flowchart showing the house model generation method. A series of flows of the respective steps will be described first, and then detailed description will be made.

First, the selection of the purpose of use of a house model is received by the purpose selection-receiving unit 110A (purpose-of-use selection step: Step S01). Next, the designation of a part type is received by the part type designation-receiving unit 110B (part type selection step: Step S02). Next, input points are received by the input point-receiving unit 110C (input point reception step: Step S03). Next, a part model is generated by the part model-generating unit 110D according to the input points (part model generation step: Step S04). Next, the generated part model is moved by the position adjustment unit 110E (position adjustment step: Step S05). Next, the state information of the part model is stored in association with the part model by the storage control unit 110F (damage storage step: Step S06).

Next, the generation of the house model corresponding to the purpose of use will be described using specific examples (a residence damage certification survey, a fixed property tax survey, and an urban planning survey). In the house model generation device 100 according to the embodiment of the present invention, house models for various purposes of use can be generated as described below. Therefore, in the house model generation device 100, it is possible to efficiently generate a house model according to the purpose of use without changing the house model generation device.

### First Embodiment/Residence Damage Certification Survey

First, an example of the generation of part models constituting a house model for which the purpose of use is the residence damage certification survey will be described.

In the residence damage certification survey performed in a case of a disaster by a local government, it is necessary to create a plan view or an elevation view of a house struck by a disaster and to record a damaged portion in the created drawing in order to leave the basis for damage certification. However, it takes time to create a plan view or an elevation view on paper. In particular, in a case where a large-scale disaster occurs, the creation of a drawing on paper is highly burdensome. Further, granularity and accuracy in the drawing on paper vary depending on a person who makes the drawing. Therefore, a house model having necessary and sufficient accuracy corresponding to the residence damage certification survey is simply generated by the house model generation device 100. Furthermore, since parts of the house model and state information (for example, a damage image) are stored in association with each other, a load on the generation of the drawing on paper is reduced, a difference depending on a person who makes the drawing is suppressed. As a result, the residence damage certification survey can be performed more efficiently. A specific example of the generation of part models constituting a house model for which the purpose of use is the residence damage certification survey will be described below.

### <Purpose-of-Use Selection Step and Part Type Selection Step>

The purpose-of-use selection step (Step S01) and the part type selection step (Step S02) will be described.

First, the purpose of use of the house model is selected by a user. For example, the user selects one purpose of use from a residence damage certification survey service, a fixed property tax survey service, an urban planning survey service, and a vacant house management service. In the present embodiment, the user selects the residence damage certification survey using the operation unit 160.

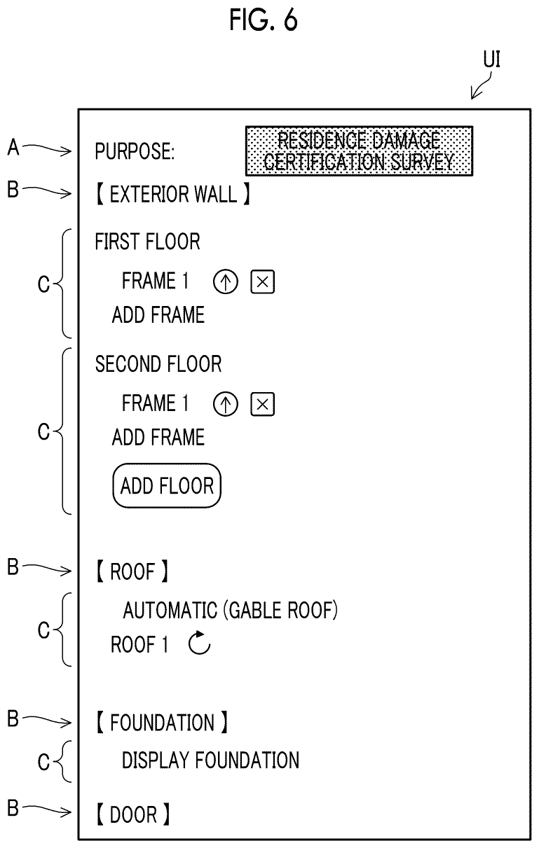

FIG. 6 is a diagram illustrating an example of a user interface UI displayed on the display unit 140.

The user interface UI includes a purpose-of-use display A, part type menu displays B, and operation menu displays C. In a case of the present embodiment, the residence damage certification survey is displayed in the purpose-of-use display A. Further, part types that can be generated, such as an exterior wall, a roof, a foundation, and a door, are displayed in the part type menu displays B based on the part type information (see FIG. 2). Furthermore, information on operations in a case of generating part models is displayed in the operation menu displays C. For example, a frame is added, so that a part model of an exterior wall is added. In addition, an exterior wall (frame) is added to a gable roof, so that a part model of a roof is added based on the position of the exterior wall (automatically). Moreover, a foundation is displayed as a part model of a foundation.

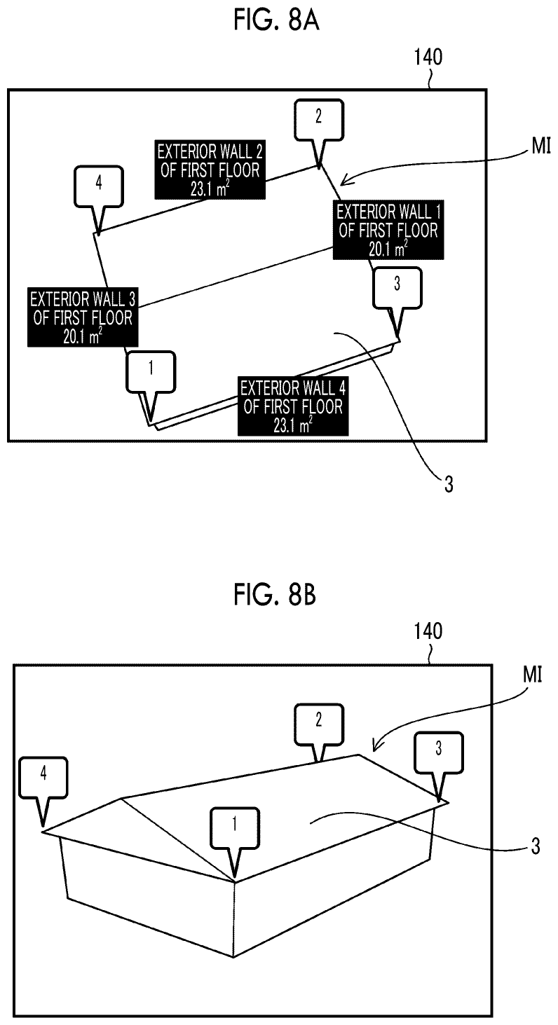

The user selects a part type to be generated using the user interface UI. For example, the user selects an exterior wall in the part type menu display B and selects the first floor and the addition of frames in the operation menu display C. Accordingly, the part type designation-receiving unit 110B receives the designation of the exterior walls of the first floor. A part model of exterior walls is generated as exterior walls constituting frames (see FIGS. 8A and 8B).

### <Input Point Reception Step and Part Model Generation Step>

Next, the input point reception step (Step S03) and the part model generation step (Step S04) will be described.

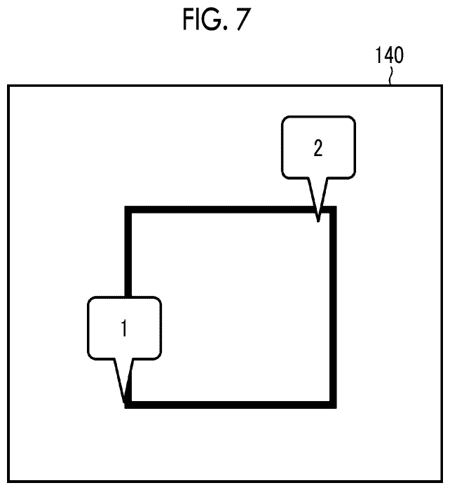

FIG. 7 is a diagram illustrating input points designated on the display unit 140.

In the input point reception step, the user inputs a first input point and a second input point on the display unit 140 using, for example, a pointing device constituting the operation unit 160, and the input point-receiving unit 110C receives the positions (for example, coordinates) of the first input point and the second input point. In the present example, the first input point and the second input point opposite to the first input point are input, so that a rectangular shape is set. This rectangular shape is formed by first to fourth input points to be described later (see FIGS. 8A and 8B). Here, in a case where the exterior walls of the first floor are selected in the residence damage certification survey, a part model of exterior walls of the first floor is formed using the input points as points (feature points) at four corners of the first floor, based on the interpretation information (see FIG. 3). Next, the part model of exterior walls of the first floor, which is generated based on the first to fourth input points, will be described. A map stored in the database 130 in advance may be displayed on the display unit 140, and then the input points may be input onto the map. In that case, the part model is generated at the positions on the map at which the input points are input.

FIGS. 8A and 8B are diagrams showing an example of the generated part model of exterior walls of the first floor.

The first input point and the second input point are input as described in FIG. 7, so that the first to fourth input points forming a rectangle are input. Then, the part model (frame) of exterior walls of the first floor is generated by the part model-generating unit 110D based on the first to fourth input points and the interpretation information (FIG. 3). FIG. 8A is a diagram showing a part model M1 of exterior walls of the first floor from above, and FIG. 8B is a diagram showing the part model M1 from the side.

The part model M1 is a part model of exterior walls of the first floor that includes the first to fourth input points as four corners. Further, a part model 3 of a gable roof is also generated based on exterior walls 1 to 4 that are generated based on the first to fourth input points.

A part type is selected and input points are input in the present embodiment as described above, so that a part model having necessary and sufficient accuracy to correspond to the residence damage certification survey can be easily generated.

### <Position Adjustment Step>

Next, the position adjustment step (Step S05) will be described. The position adjustment unit 110E receives an instruction to move a part model displayed on the display unit 140 from the user. Then, the position adjustment unit 110E moves the part model displayed on the display unit 140. Accordingly, the user can adjust the position of the part model.

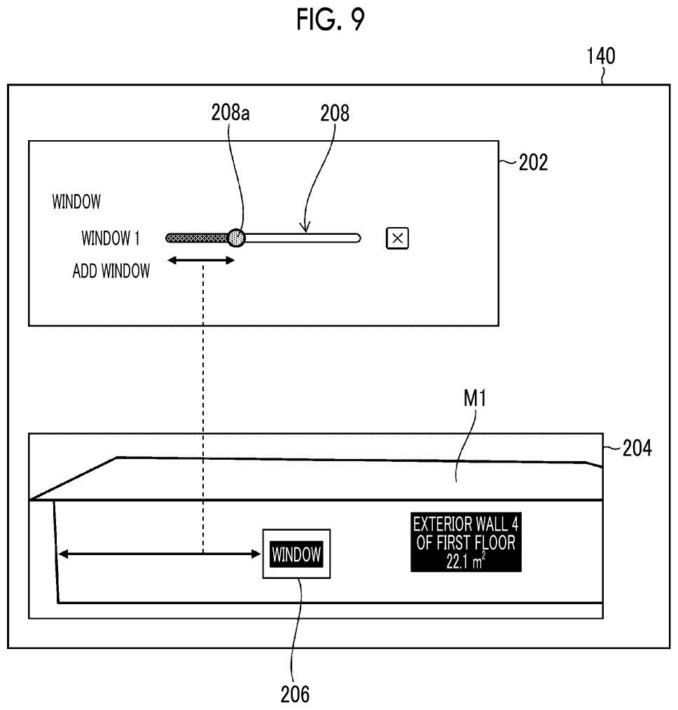

FIG. 9 is a diagram illustrating the adjustment of the position of the part model.

A movement input user interface 202 and a house model display 204 are displayed on the display unit 140. A movement adjustment bar 208 is displayed on the movement input user interface 202. The user can move a pointer 208a of the movement adjustment bar 208 to input an instruction to move a part model 206 of a window. The position adjustment unit 110E moves the part model 206 of the window with respect to the part model M1 in response to the instruction to move the part model 206 that is input via the movement adjustment bar 208. For example, the position adjustment unit 110E moves the part model 206 of the window in conjunction with the movement of the pointer 208a.

As described above, in the position adjustment step, the position adjustment unit 110E receives an instruction to move the part model, and moves the part model in response to the instruction to move the part model. Accordingly, it is possible to adjust the position of the part model, and to generate a house model that is intended by the user.

### <Damage Storage Step>

Next, the damage storage step (Step S06) will be described. In the damage storage step, the generated house model and state information of an actual house are stored in association with each other. For example, the storage control unit 110F receives selection of a portion on the part model on the display unit 140, and stores state information of the part model in association with the selected portion.

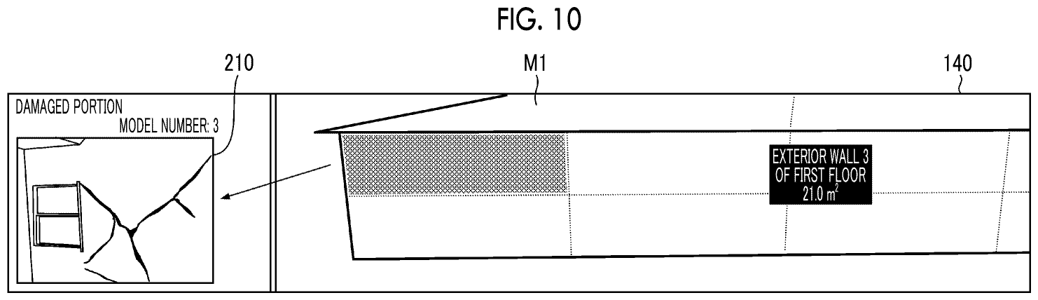

FIG. 10 is a diagram illustrating Specific example 1 of storage of the state information.

The part model M1 of exterior walls of the first floor is displayed on the display unit 140. In this case, an exterior wall 1 of the part model M1 of exterior walls of the first floor is displayed to be divided into grids. Further, the damage image 210 (an image showing the state information) is displayed on the display unit 140. The damage image 210 is an image in which an exterior wall corresponding to the part model M1 is imaged. Then, the user selects one grid of the part model M1, and the selected grid and the damage image 210 are stored in association with each other by the storage control unit 110F.

As described above, in the damage storage step, a portion on the part model M1 and the damage image 210 are stored in the database 130 in association with each other by the storage control unit 110F. Accordingly, in a case where the residence damage certification survey is performed, the generated house model can be more effectively used.

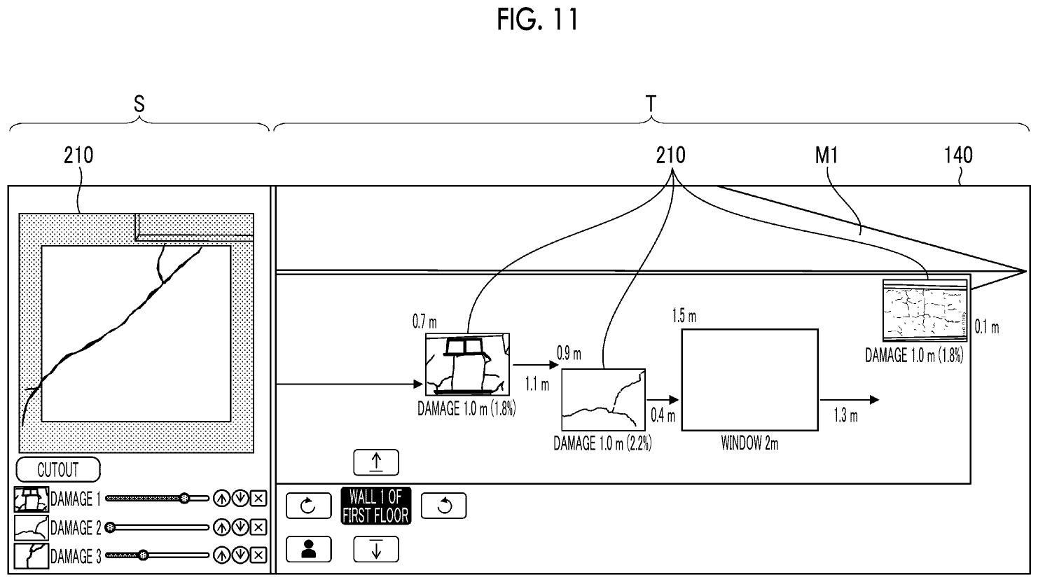

FIG. 11 is a diagram illustrating Specific example 2 of the storage of the state information.

An image editing display S and a damage image display T are displayed on the display unit 140. The part model M1 of exterior walls of the first floor is displayed in the damage image display T, and the damage image 210 is displayed with a texture on the surface (exterior wall) of the part model M1. The display of the damage image 210 with a texture can be performed with any size at any position. Therefore, the user can display the damage image 210 with a texture in accordance with the position of damage to an actual house. The part model M1 and the damage image 210, which is displayed with a texture, are stored in the database 130 in association with each other by the storage control unit 110F.

Further, the damage image 210 to be displayed with a texture can be edited in the image editing display S. For example, in the image editing display S, cutout editing can be performed on the damage image 210 that is displayed with a texture.

The specific example in which the damage image 210 is used as the state information or an image indicating the state information has been described in the above description, but an example of the state information or the image indicating the state information is not limited to the damage image.

As described above, in the damage storage step, the damage image 210 is disposed on the surface of the part model M1 and the part model M1 and the damage image 210 are stored in the database 130 in association with each other by the storage control unit 110F. Accordingly, in a case where the residence damage certification survey is performed, the generated house model can be more effectively used.

### Second Embodiment/Fixed Property Tax Survey

Next, an example of the generation of part models constituting a house model in a case where the purpose of use is the fixed property tax survey will be described. A house model that is used in the fixed property tax survey can also be generated by the house model generation device 100, like the house model that is used in the residence damage certification survey described above. Therefore, in the house model generation device 100, it is possible to efficiently generate a house model according to the purpose of use without changing the house model generation device. Further, the description of the portions already described in the first embodiment described above will be omitted, and portions different from those in the first embodiment will be mainly described.

As in the residence damage certification survey described in the first embodiment, a three-dimensional house model is also used in the fixed property tax survey (the survey of a house related to a fixed property tax) which is a local government service. In the fixed property tax survey, a lot of time is required to create drawings that are used to three-dimensionally record an extension and a reconstructed portion, to enter assessment, and to register data in a system. Therefore, a house model having necessary and sufficient accuracy is simply generated according to the fixed property tax survey by the house model generation device 100. Accordingly, it is possible to more efficiently perform the fixed property tax survey.

### <Part Model of Exterior Walls of First Floor>

First, the generation of the part model of exterior walls of the first floor in the fixed property tax survey will be described.

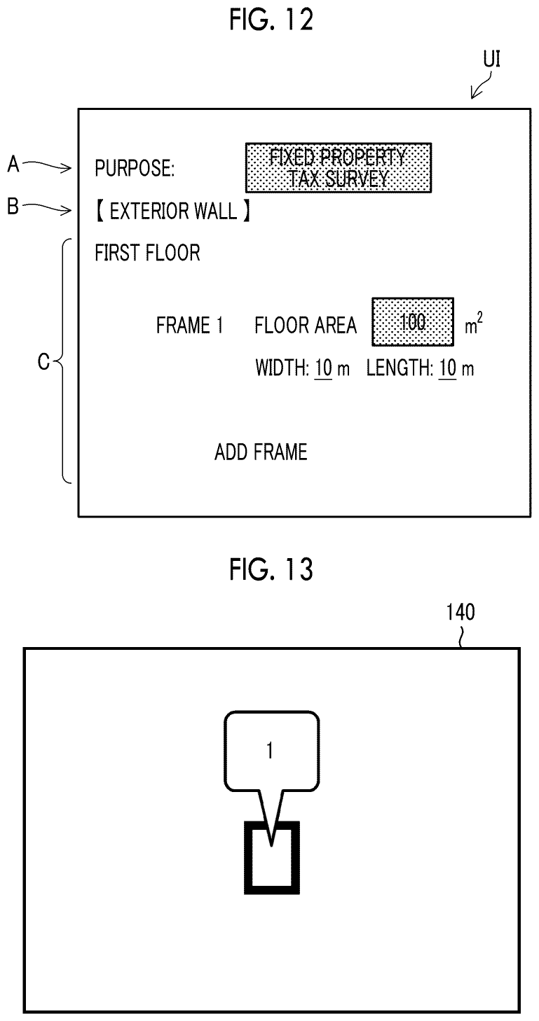

FIG. 12 is a diagram illustrating an example of a user interface UI displayed on the display unit 140.

The user interface UI includes a purpose-of-use display A, a part type menu display B, and an operation menu display C. In the case of the present embodiment, the fixed property tax survey is displayed in the purpose-of-use display A. Further, an exterior wall is displayed in the part type menu display B as a part type that can be generated. Furthermore, a menu display to which dimensions are to be input is displayed in the operation menu display C. Then, a user inputs a floor area of 100 m² via the operation unit 160. Accordingly, the part type designation-receiving unit 110B receives the designation of an exterior wall and an input of the exterior wall to the shape input menu.

Since the dimensions and the finish of each part of the house are important in the calculation of a fixed property tax, an operation menu of the part model is formed of a shape input menu display to which dimensions are to be input as shown in FIG. 12 and a method is switched to a method of creating a part model based on the input dimensions. Information on a shape input menu to which information on shapes of a plurality of part types is to be input is stored in the database 130 according to each of the purposes of use. Specifically, in a case where the purpose of use is the fixed property tax survey and a part model of exterior walls is generated, a fact that a menu display to which dimensions are to be input is displayed as a shape input menu is stored in the database 130.

FIG. 13 is a diagram illustrating an input point designated on the display unit 140.

The user designates a point (feature point) that is the coordinates of a center of a frame 1 on a map as a first input point. The part model of exterior walls is generated as a frame.

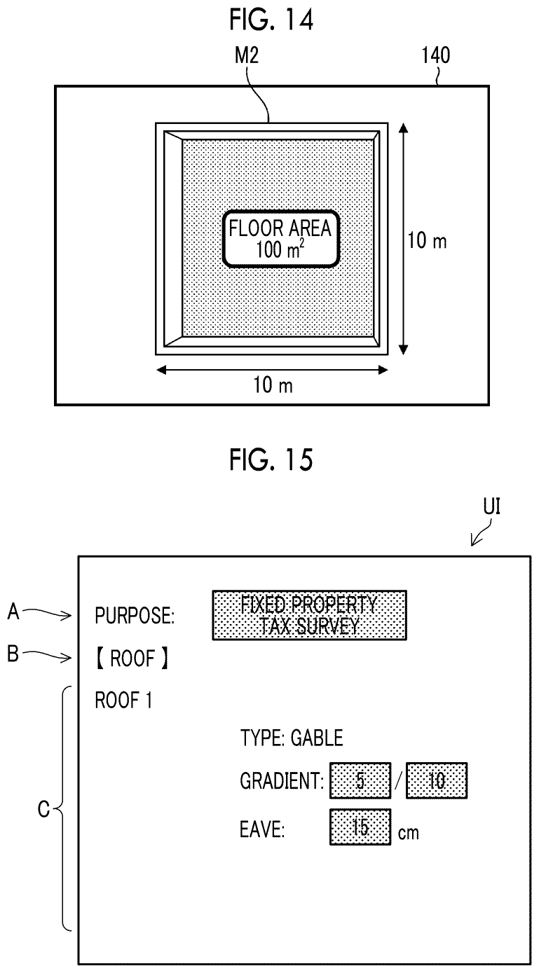

FIG. 14 is a diagram showing an example of a generated part model of exterior walls of a first floor.

The part model-generating unit 110D generates a part model M2 of exterior walls of the first floor that satisfies designated dimensions (a floor area is 100 m²) with the coordinates (input point) designated in FIG. 13 as a center. The part model of exterior walls of the first floor can be edited by a change in dimensions in the operation menu or the movement, addition, or deletion of a vertex of the part model of the exterior wall of the first floor.

### <Part Model of Roof>

Next, the generation of the part model of a roof in the fixed property tax survey will be described.

FIG. 15 is a diagram illustrating an example of a user interface UI displayed on the display unit 140.

The user interface UI includes a purpose-of-use display A, a part type menu display B, and an operation menu display C. In the case of the present embodiment, the fixed property tax survey is displayed in the purpose-of-use display A. Further, a roof is displayed in the part type menu display B as a part type that can be generated. Furthermore, a menu display to which a gradient and dimensions of an cave are to be input is displayed in the operation menu display C. Then, a user inputs a gradient of 5/10 and an cave of 15 cm via the operation unit 160. Accordingly, the part type designation-receiving unit 110B receives the designation of a roof and an input of the roof to the shape input menu. In a case where the purpose of use is the fixed property tax survey and the part model of a roof is generated, a fact that the menu display to which a gradient and dimensions of an cave are to be input is displayed as the shape input menu is stored in the database 130.

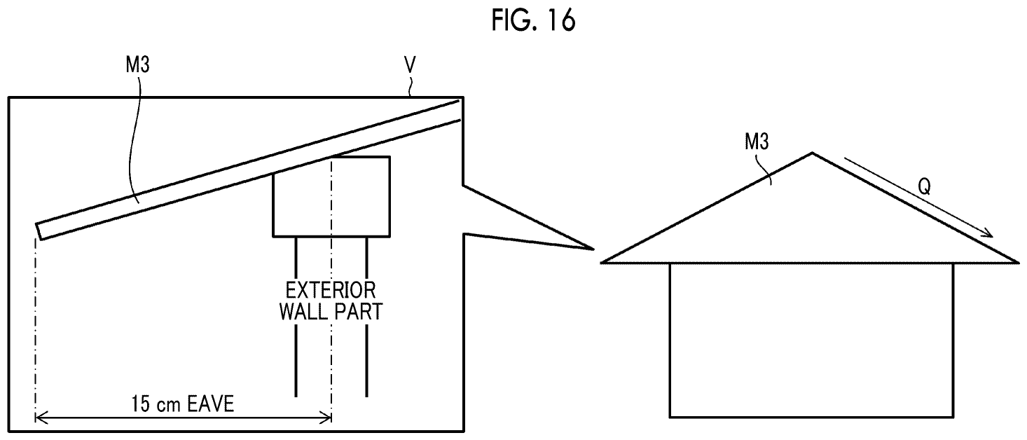

FIG. 16 is a diagram illustrating the part model of a roof of the present embodiment.

The gradient and the dimensions of an cave, which are input to the shape input menu, are reflected in the generated part model M3 of a roof. Specifically, the part model M3 is generated such that the dimensions of an cave is 15 cm as shown in an enlarged view V, and the part model M3 is generated such that a gradient Q is 5/10.

Even in a case where the purpose of use of the house model is the fixed property tax survey as described above, a part model having necessary and sufficient accuracy to correspond to the fixed property tax survey can be easily generated.

### Third Embodiment/Urban Planning Survey

Next, an example of the generation of part models constituting a house model in a case where the purpose of use is the urban planning survey will be described. A house model that is used in the urban planning survey can also be generated by the house model generation device 100, like the house models that are used in the residence damage certification survey and the fixed property tax survey described above. Therefore, in the house model generation device 100, it is possible to efficiently generate a house model according to the purpose of use without changing the house model generation device. The description of the portions already described in the first and second embodiments described above will be omitted, and portions different from those in the first and second embodiments will be mainly described. Since a purpose in the urban planning survey is to collect information on the current state of use of a building, detailed shape information is not necessary. Therefore, a menu of only the minimum necessary exterior wall is displayed in the preset setting.

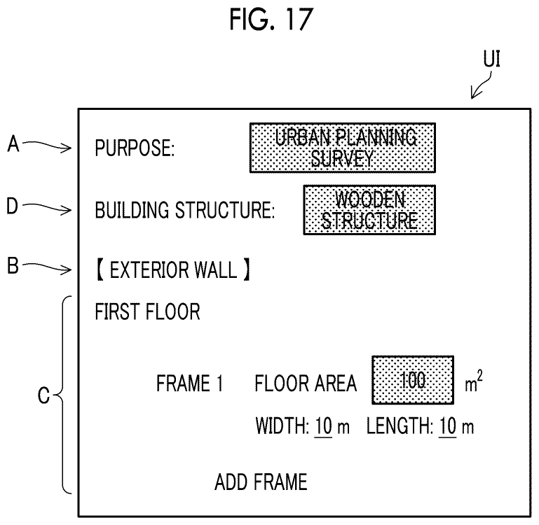

FIG. 17 is a diagram illustrating an example of a user interface UI displayed on the display unit 140.

The user interface UI includes a purpose-of-use display A, a part type menu display B, an operation menu display C, and a building structure D. In the case of the present embodiment, the urban planning survey is displayed in the purpose-of-use display A. Further, only the minimum necessary exterior wall is displayed in the part type menu display B as a part type that can be generated. Furthermore, a menu display to which dimensions are to be input is displayed in the operation menu display C. In addition, a wooden structure is selected and displayed as the building structure. Examples of a building structure type include a wooden structure, a traditional Japanese fireproof structure, a steel-reinforced concrete structure, a reinforced concrete structure, a steel structure, a lightweight steel structure, a brick structure, a concrete block structure, and a stone structure. The user selects and inputs one building structure type from these building types via the operation unit 160.

Even in a case where the purpose of use of the house model is the urban planning survey as described above, a part model having necessary and sufficient accuracy to correspond to the urban planning survey can be easily generated.

### <Example of Generation of Other Part Models/Part Model of Exterior Walls of Second Floor>

Next, another example of the input point reception step and the part model generation step in a case where the purpose of use is the residence damage certification survey will be described. An example of a case where a part model of exterior walls of a second floor in the residence damage certification survey is generated will be described in the present example.

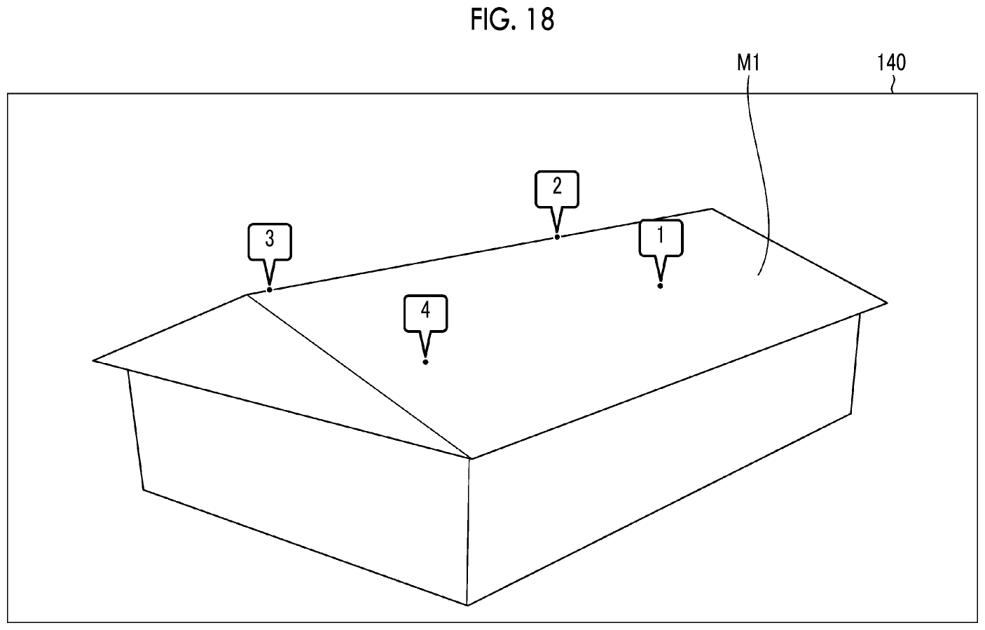

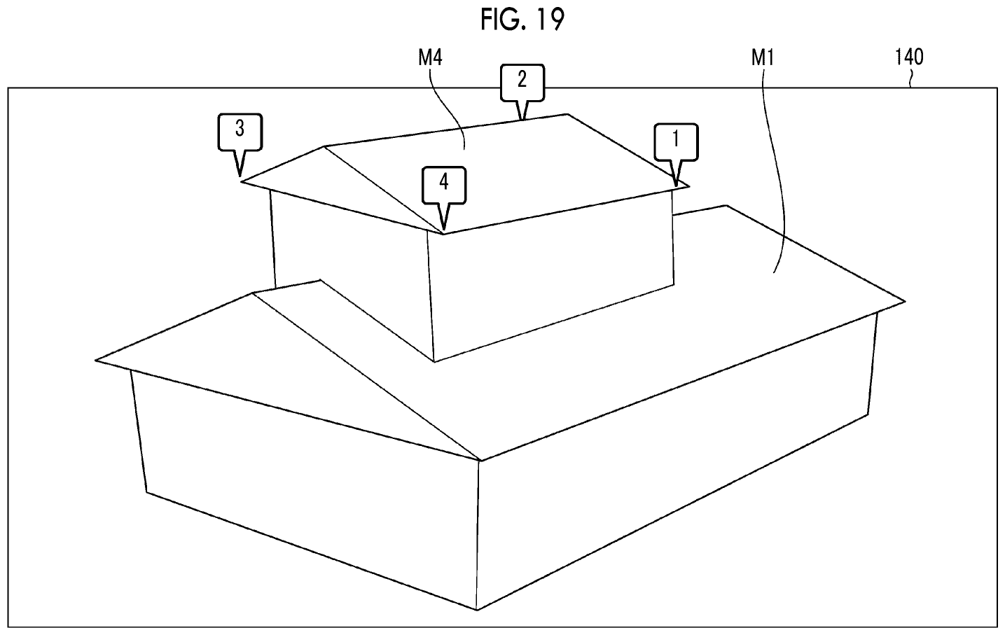

FIGS. 18 and 19 are diagrams illustrating another example of the input point reception step and the part model generation step.

In a case shown in FIG. 18, a first input point, a second input point, a third input point, and a fourth input point are input to form a rectangular shape by a pointing device constituting the operation unit 160. Further, the first to fourth input points are designated in a ceiling surface of a first floor. Accordingly, the input point-receiving unit 110C receives the inputs of the first to fourth input points.

Further, in a case where the purpose of use is the residence damage certification survey and an exterior wall of the second floor is selected as a part type, a part model M2 of exterior walls of the second floor is formed using the first to fourth input points as points (feature points) at four corners of the second floor, based on the interpretation information (see FIG. 3).

FIG. 19 is a diagram showing an example of the generated part model of exterior walls of the second floor.

The part model-generating unit 110D generates a part model M4 based on the first to fourth input points and the interpretation information (FIG. 3) described in FIG. 18. The part model M4 is a part model of exterior walls of the second floor that includes the first to fourth input points as four corners. As described above, even in the case of the part model M4 of exterior walls of the second floor in the residence damage certification survey, a part model having necessary and sufficient accuracy to correspond to the residence damage certification survey can be easily generated.

### <Others>

In the above-described embodiments, the hardware structures of processing units that execute various types of processing (the purpose selection-receiving unit 110A, the part type designation-receiving unit 110B, the input point-receiving unit 110C, the part model-generating unit 110D, the position adjustment unit 110E, the storage control unit 110F, and the display control unit) are various processors to be described below. The various processors include: a central processing unit (CPU) that is a general-purpose processor functioning as various processing units by executing software (programs); a programmable logic device (PLD) that is a processor of which the circuit configuration can be changed after manufacture, such as a field programmable gate array (FPGA); a dedicated electrical circuit that is a processor having a circuit configuration designed exclusively to perform specific processing, such as an application specific integrated circuit (ASIC); and the like.

One processing unit may be configured of one of these various processors, or may be configured of two or more processors of the same type or different types (for example, a plurality of FPGAs or a combination of a CPU and an FPGA). Further, a plurality of processing units may be configured of one processor. As an example where a plurality of processing units are configured of one processor, first, there is an aspect where one processor is configured of a combination of one or more CPUs and software as typified by a computer, such as a client or a server, and functions as a plurality of processing units. Second, there is an aspect where a processor fulfilling the functions of the entire system, which includes a plurality of processing units, using one integrated circuit (IC) chip as typified by System On Chip (SoC) or the like is used. As described above, various processing units are formed using one or more of the above-described various processors as hardware structures.

In addition, the hardware structures of these various processors are more specifically electrical circuitry where circuit elements, such as semiconductor elements, are combined.

Each configuration and function having been described above can be appropriately realized by arbitrary hardware, arbitrary software, or a combination of both arbitrary hardware and arbitrary software. For example, the present invention can also be applied to a program that causes a computer to perform the above-mentioned processing steps (processing procedure), a computer-readable recording medium (non-transitory recording medium) in which such a program is recorded, or a computer in which such a program can be installed.

The embodiments of the present invention have been described above, but it goes without saying that the present invention is not limited to the above-mentioned embodiments and may have various modifications without departing from the scope of the present invention.

### EXPLANATION OF REFERENCES

100: house model generation device
110: processor
110A: purpose selection-receiving unit
110B: part type designation-receiving unit
110C: input point-receiving unit
110D: part model-generating unit
110E: position adjustment unit
110F: storage control unit
120: memory
130: database
140: display unit
150: input/output interface
160: operation unit

What is claimed is:

1. A house model generation device comprising:
a memory that stores information on a plurality of part types of part models, which are generatable according to each of a plurality of purposes of use of a three-dimensional house model and constitute the house model, and interpretation information on a relationship between an input point and a feature point of a part for each of the plurality of part types; and
a processor,
wherein the processor is configured to:
receive selection of a purpose of use of the house model to be generated among the plurality of purposes of use;
receive designation of one part type among a plurality of generatable part types according to the selected purpose of use;
receive the input point input by being designated on a display unit; and
generate a part model, which corresponds to the designated part type and constitutes the house model, based on the input point and the interpretation information.

2. The house model generation device according to claim 1,
wherein the memory stores information on a shape input menu to which information on shapes of the plurality of part types is to be input according to each of the plurality of purposes of use, and
the processor is configured to:
receive an input of the shape input menu according to the designated part type; and
generate a part model, which corresponds to the designated part type and constitutes the house model, based on the input of the shape input menu.

3. The house model generation device according to claim 1,
wherein the plurality of purposes of use of the house model include two or more purposes of a residence damage certification survey service, a fixed property tax survey service, an urban planning service, and a vacant house management service.

4. The house model generation device according to claim 1,
wherein the interpretation information in a case where the part type is an exterior wall of a first floor is information on a relationship in which the input point forms a feature point of the exterior wall of the first floor in a case where a point on a ground surface on the display unit is input as the input point.

5. The house model generation device according to claim 1,
wherein the interpretation information in a case where the part type is an exterior wall of a second floor or higher is information on a relationship in which the input point forms a feature point of the exterior wall of the second floor or higher in a case where a point in a ceiling surface of an immediately lower floor on the display unit is input as the input point.

6. The house model generation device according to claim 1,
wherein the interpretation information in a case where the part type is a window is information on a relationship in which the input point forms a feature point of the window in a case where a point in a surface of an exterior wall on the display unit is input as the input point.

7. The house model generation device according to claim 1,
wherein the interpretation information in a case where the part type is a door is information on a relationship in which the input point forms a feature point of the door in a case where a point in a surface of an exterior wall on the display unit is input as the input point.

8. The house model generation device according to claim 1,
wherein the interpretation information in a case where the part type is an exterior wall is information on a relationship in which the input point forms a feature point of the exterior wall in a case where a point on the display unit is input as the input point, and
the part models of the exterior wall and a roof provided on the exterior wall are generated based on the input point and the interpretation information.

9. The house model generation device according to claim 1,
wherein the processor is configured to:
receive selection of a portion on the part model on the display unit; and
store state information of the part model in association with the selected portion.

10. The house model generation device according to claim 1,
wherein the processor is configured to dispose an image, which indicates state information of the part model, on a surface of the part model displayed on the display unit.

11. The house model generation device according to claim 1,
wherein the processor is configured to display the generated part model on the display unit and to receive an instruction to move a position of the part model.

12. The house model generation device according to claim 1,
wherein the part types are an exterior wall, an interior wall, a roof, a foundation, a column, a beam, a floor, a ceiling, a building fixture, a window, a door, and equipment.

13. A house model generation method executed by a processor of a house model generation device including a memory that stores information on a plurality of part types of part models, which are generatable according to each of a plurality of purposes of use of a three-dimensional house model and constitute the house model, and interpretation information on a relationship between an input point and a feature point of a part for each of the plurality of part types, and the processor, the house model generation method comprising:
a step of receiving selection of a purpose of use of the house model to be generated among the plurality of purposes of use;
a step of receiving designation of one part type among a plurality of generatable part types according to the selected purpose of use;
a step of receiving the input point input by being designated on a display unit; and
a step of generating a part model, which corresponds to the designated part type and constitutes the house model, based on the input point and the interpretation information.

14. A non-transitory, computer-readable tangible recording medium on which a program for causing, when read by a computer, a processor of the computer to execute the house model generation method according to claim 13 is recorded.
